(19) United States
(12) Patent Application Publication
(10) Pub. No.: US 2025/0306122 A1
(43) Pub. Date: Oct. 2, 2025

(54) DETERIORATION DETERMINATION DEVICE FOR LITHIUM ION CAPACITOR

(71) Applicant: TOYOTA JIDOSHA KABUSHIKI KAISHA, Toyota-shi (JP)

(72) Inventor: Yukiyoshi UENO, Toyota-shi (JP)

(73) Assignee: TOYOTA JIDOSHA KABUSHIKI KAISHA, Toyota-shi (JP)

(21) Appl. No.: 19/015,674

(22) Filed: Jan. 10, 2025

(30) Foreign Application Priority Data
Mar. 28, 2024 (JP) 2024-053094

(51) Int. Cl. G01R 31/392; G01R 31/367; G01R 31/3835; G01R 31/389

(52) U.S. Cl. CPC G01R 31/392; G01R 31/367; G01R 31/3835; G01R 31/389

(57) ABSTRACT

A deterioration determination device for a lithium ion capacitor includes a storage unit that stores SOC-OCV characteristics of the lithium ion capacitor, an acquisition unit that acquires a voltage of the lithium ion capacitor, a charging and discharging control unit that causes the lithium ion capacitor to perform a predetermined charge/discharge process, a calculation unit that calculates a resistance value of the lithium ion capacitor from a difference between a first voltage after the charge/discharge process and a second voltage after the charge/discharge process estimated from SOC-OCV characteristics, and a determination unit that determines a deterioration state of the lithium ion capacitor based on the resistance value.

### CROSS-REFERENCE TO RELATED APPLICATION

This application claims priority to Japanese Patent Application No. 2024-053094 filed on Mar. 28, 2024, incorporated herein by reference in its entirety.

### BACKGROUND

### 1. Technical Field

The present disclosure relates to a device for diagnosing a lithium ion capacitor and determining whether the capacitor is in a deteriorated state.

### 2. Description of Related Art

Japanese Unexamined Patent Application Publication No. 2019-186988 (JP 2019-186988 A) discloses a charging and discharging control device for a lithium ion capacitor for the purpose of eliminating deterioration of the lithium ion capacitor and suppressing a decrease in performance.

### SUMMARY

As a general method for determining deterioration of a lithium ion capacitor, there is known a method in which capacitance measurement and resistance value measurement are individually performed and the deterioration is determined from the measurement results. In this related-art method, however, a long time is required for each measurement, and a time for stabilizing the state of the lithium ion capacitor needs to be provided between the first measurement and the next measurement in order to improve the accuracy of the determination. Therefore, there is room for further study on the method for determining deterioration of a lithium ion capacitor in order to realize reduction in time and improvement in accuracy.

The present disclosure has been made in view of the above problems, and an object of the present disclosure is to provide a deterioration determination device for a lithium ion capacitor in which both reduction in time and improvement in accuracy can be realized in deterioration determination for the lithium ion capacitor.

In order to solve the above problems, a deterioration determination device for a lithium ion capacitor according to one aspect of the present disclosure includes:
a storage unit configured to store a state of charge-open circuit voltage characteristic of the lithium ion capacitor;
an acquisition unit configured to acquire a voltage of the lithium ion capacitor;
a charging and discharging control unit configured to cause the lithium ion capacitor to perform a predetermined charging and discharging process;
a calculation unit configured to calculate a resistance value of the lithium ion capacitor from a difference between a first voltage after the charging and discharging process that is acquired by the acquisition unit and a second voltage after the charging and discharging process that is estimated from the state of charge-open circuit voltage characteristic; and
a determination unit configured to determine a deterioration state of the lithium ion capacitor based on the resistance value.

In the deterioration determination device for the lithium ion capacitor according to the present disclosure, the resistance value can be measured simultaneously with the charging and discharging process (capacitance measurement) of the lithium ion capacitor. Therefore, it is possible to realize both reduction in time and improvement in accuracy in the deterioration determination.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of a deterioration determination device for a lithium ion capacitor and a peripheral portion thereof according to an embodiment of the present disclosure;

FIG. 2 is a flow chart of LIC degradation determination process executed by the deterioration determination device for the lithium ion capacitor;

FIG. 3 shows an exemplary SOC-OCV property of a lithium ion capacitor; and

FIG. 4 is a diagram illustrating an example of a voltage change of a lithium ion capacitor in a charging process.

### DETAILED DESCRIPTION OF EMBODIMENTS

In the lithium ion capacitor deterioration determination device of the present disclosure, the resistance value of the lithium ion capacitor is calculated by excluding the resistance component based on the capacitance variation from the resistance component obtained by the charge/discharge process (measurement of the capacitance). The calculated resistance value is used to determine the deterioration of the lithium ion capacitor. Hereinafter, an embodiment of the present disclosure will be described in detail with reference to the drawings.

### EMBODIMENT

### Configuration

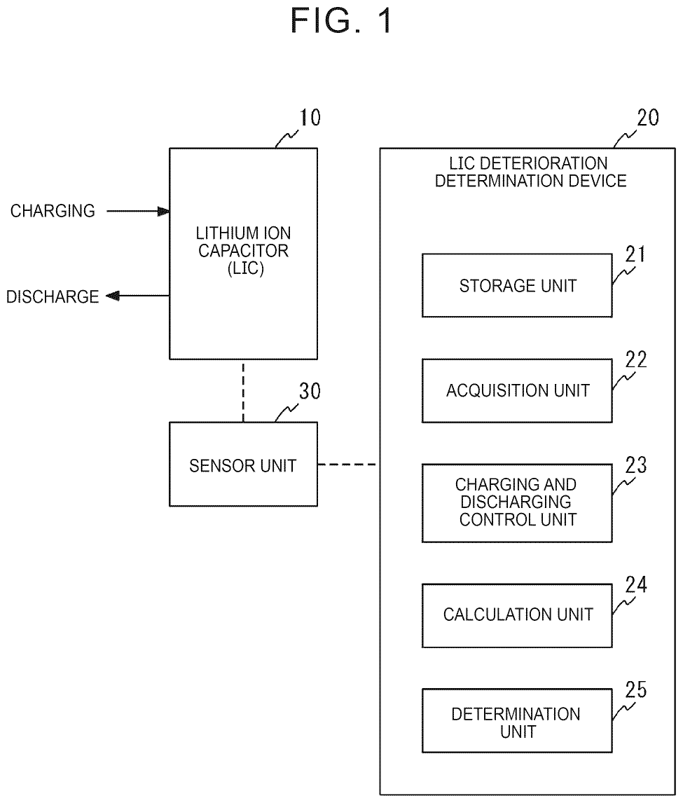

FIG. 1 is a functional block diagram of a deterioration determination device for a lithium ion capacitor and a peripheral portion thereof according to an embodiment of the present disclosure. The functional block illustrated in FIG. 1 includes a lithium ion capacitor (LIC) 10, a LIC deterioration determination device 20, and a sensor unit 30. The lithium ion capacitor 10, LIC deterioration determination device 20, and the sensor unit 30 may be mounted on vehicles, for example.

The lithium ion capacitor 10 is a power storage device having an intermediate property between a lithium ion battery (LIB) having a high energy density and an electric double layer capacitor (EDLC) having a high power density capable of being charged and discharged in a short time. The lithium ion capacitor 10 is typically configured as a stack in which a plurality of lithium ion capacitor cells is connected in series and/or in parallel. When mounted on a vehicle, the lithium ion capacitor 10 is used as a redundant sub-battery for backing up a main battery that supplies electric power to an on-vehicle load, for example.

The sensor unit 30 is configured to detect the state of the lithium ion capacitor 10. The sensor unit 30 includes a detection device. The detection device includes a voltage sensor that monitors the voltage of the lithium ion capacitor 10, a current sensor that monitors the current flowing through the lithium ion capacitor 10, a temperature sensor that monitors the temperature of the lithium ion capacitor 10, and the like. The status of the lithium ion capacitor 10 detected by the sensor unit 30 is outputted to LIC deterioration determination device 20. The sensor unit 30 may be incorporated in the lithium ion capacitor 10 or may be included in the configuration of LIC deterioration determination device 20.

LIC deterioration determination device 20 is a device for performing predetermined diagnostics on the lithium ion capacitor 10 to determine whether or not the lithium ion capacitor 10 is in a degraded condition. LIC deterioration determination device 20 includes a storage unit 21, an acquisition unit 22, a charging and discharging control unit 23, a calculation unit 24, and a determination unit 25.

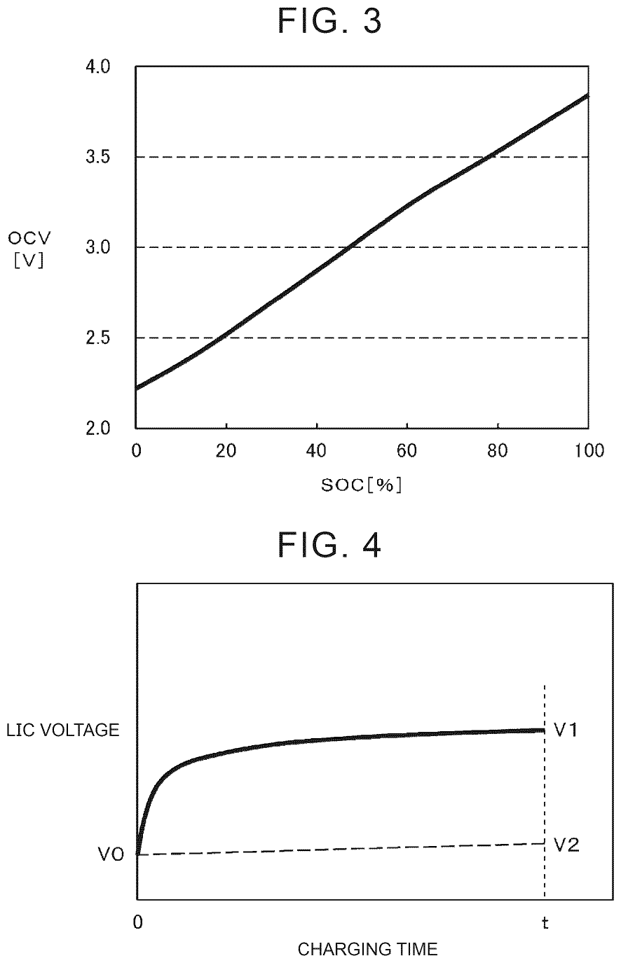

The storage unit 21 is a storage device that stores SOC-OCV properties of the lithium ion capacitor 10. SOC-OCV property is a property that correlates the storage rate (SOC: State of Charge) of the lithium ion capacitor 10 with the open-circuit-voltage (OCV: Open Circuit Voltage). FIG. 3 shows an exemplary SOC-OCV property of the lithium ion capacitor 10. As can be seen in FIG. 3, the storage rate of the lithium ion capacitor 10 and the open circuit voltage have a positive correlation that is substantially linear.

The storage unit 21 may store a plurality of SOC-OCV properties corresponding to a plurality of temperatures (for example, −10° C. or 25° C.) for the lithium ion capacitor 10. Alternatively, the storage unit 21 may store a plurality of SOC-OCV properties corresponding to a plurality of capacities (e.g., 1000 F and 1100 F). In addition, the storage unit 21 may store SOC-OCV characteristics at the time of discharging and SOC-OCV characteristics at the time of charging at the same temperature/capacitance. These SOC-OCV properties are obtained in advance by actually measuring or simulating the lithium ion capacitor 10.

The acquisition unit 22 acquires at least a voltage, a current, and a temperature as the state of the lithium ion capacitor 10 from the sensor unit 30. The information on the voltage, the current, and the temperature of the lithium ion capacitor 10 is acquired in a timely manner in order to implement the charging and discharging control unit 23 described later. The voltage and temperature of the lithium ion capacitor 10 acquired by the acquisition unit 22 are used in the calculation unit 24.

The charging and discharging control unit 23 performs control related to charging or discharging of the lithium ion capacitor 10. The charging and discharging control unit 23 performs a charge/discharge process of the lithium ion capacitor 10 by controlling a charge/discharge device (not shown) such as a DCDC converter connected to the lithium ion capacitor 10. The charging and discharging process performed by the charging and discharging control unit 23 will be described later.

The calculation unit 24 estimates the voltage of the lithium ion capacitor 10 after the charge/discharge process is performed by the charging and discharging control unit 23 from SOC-OCV property stored in the storage unit 21. Further, the calculation unit 24 calculates the resistance value of the lithium ion capacitor 10 based on the voltage difference between the lithium ion capacitors 10 before and after the charge/discharge process is performed. The estimation and calculation performed by the calculation unit 24 will be described later.

The determination unit 25 determines the deterioration of the lithium ion capacitor 10 based on the resistance value of the lithium ion capacitor 10 calculated by the calculation unit 24. The deterioration determination performed by the determination unit 25 will be described later.

Note that a part or all of LIC deterioration determination device 20 described above may typically be configured as a processor such as a microcomputer, a memory, an Electronic Control Unit (ECU) including an input/output interface, and the like. The electronic control device can realize some or all of the functions of the acquisition unit 22, the charging and discharging control unit 23, the calculation unit 24, and the determination unit 25 by the processor reading and executing the program stored in the memory.

### Control

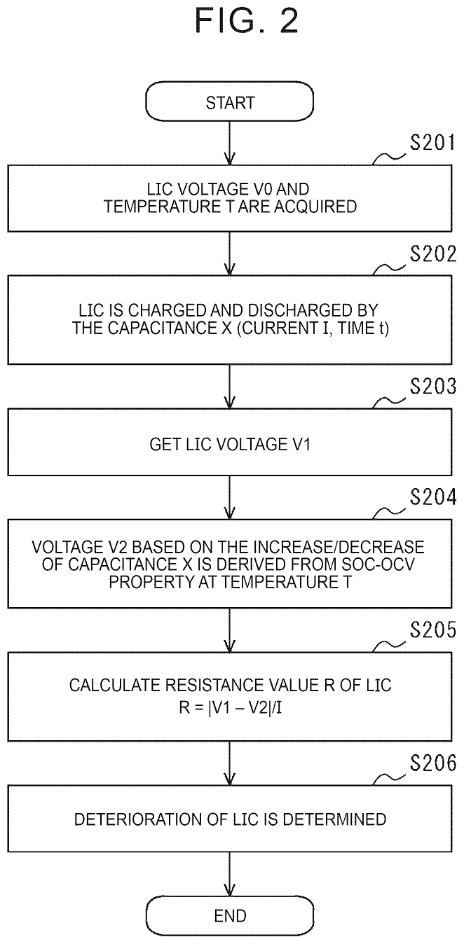

Next, the control executed by LIC deterioration determination device 20 according to the present embodiment will be described with reference to FIGS. 2 and 4. FIG. 2 is a flow chart for explaining the sequence of LIC degradation determination process executed by the respective components of LIC deterioration determination device 20. FIG. 4 is a diagram illustrating an example of a voltage change of the lithium ion capacitor 10 in the charging process.

LIC degradation determination process illustrated in FIG. 2 is started, for example, when a predetermined timing (e.g., updating timing of the degradation determination) at which the status of the lithium ion capacitor 10 is desired to be checked is reached.

### S201

The acquisition unit 22 acquires the voltage V0 [V] and the temperature T [° C.] of the lithium ion capacitor (LIC) 10 from the sensor unit 30. The voltage V0 acquired by the acquisition unit 22 is the voltage of the lithium ion capacitor 10 prior to the charge/discharge process performed by the charging and discharging control unit 23.

When the voltage V0 and the temperature T of the lithium ion capacitor 10 are acquired by the acquisition unit 22, the process proceeds to S202.

### S202

The charging and discharging control unit 23 performs a charge/discharge process in the lithium ion capacitor (LIC) 10. More specifically, the charging and discharging control unit 23 performs a process of causing a constant current I [A] to flow into the lithium ion capacitor 10 by a predetermined time t [h], that is, a process of charging the capacitance X (=I×t) [Ah] to the lithium ion capacitor 10. Alternatively, the charging and discharging control unit 23 performs a process of causing a constant current I to flow out of the lithium ion capacitor 10 for a predetermined time t, that is, a process of discharging the capacitance X from the lithium ion capacitor 10. A solid line in FIG. 4 shows a state of a voltage change of the lithium ion capacitor 10 when charging is performed only for the time t with a constant current I. Note that the current I and the time t can be appropriately set based on the storage capacitance, the performance, and the like of the lithium ion capacitor 10.

When the charging/discharging process of the lithium ion capacitor 10 by the capacitance X is performed by the charging and discharging control unit 23, the process proceeds to S203.

### S203

The acquisition unit 22 acquires the voltage V1 (first voltage) [V] of the lithium ion capacitor (LIC) 10 from the sensor unit 30. Here, the voltage V1 acquired by the acquisition unit 22 becomes the voltage of the lithium ion capacitor 10 after the charging and discharging process by the charging and discharging control unit 23 is performed (see FIG. 4). The voltage V1 includes both components of a voltage variation caused by an increase or decrease in the capacitance X due to charging and discharging and a voltage variation caused by a change in the resistance value due to a charging and discharging action.

When the acquisition unit 22 obtains the voltage V1 of the lithium ion capacitor 10, the process proceeds to S204.

### S204

The calculation unit 24 derives a voltage variation caused by an increase or decrease in the capacitance X due to charging and discharging based on SOC-OCV property of the lithium ion capacitor 10 stored in the storage unit 21. More specifically, the calculation unit 24 specifies a SOC-OCV characteristic corresponding to the temperature T (further, the capacitance of the lithium ion capacitor 10) from among the plurality of SOC-OCV characteristics stored in the storage unit 21. When the charge process is performed in S202, the calculation unit 24 derives the voltage V2 (second voltage) [V]. The voltage V2 (second voltage) [V] corresponds to the storage rate SOC2 (=SOC0+X/full-charge capacitance×100) obtained by increasing the capacitance X from the storage rate SOC0 corresponding to the open-circuit voltage=voltage V0 in the specified SOC-OCV property. Alternatively, when the discharging process is performed in the above-described S202, the calculation unit 24 derives a voltage V2 corresponding to the power storage rate SOC2 (=SOC0−X/full charge capacitance×100) obtained by decreasing the capacitance X from the power storage rate SOC0. Therefore, the voltage V2 is only a component corresponding to a voltage variation caused by an increase or decrease in the capacitance X due to charging and discharging. SOC-OCV property corresponding to the temperature T can be, for example, a SOC-OCV property having a temperature closest to the temperature T. The broken line in FIG. 4 shows an image in which the voltage (LIC voltage) of the lithium ion capacitor 10 changes from the voltage V0 to the voltage V2 on SOC-OCV property due to an increase in the capacitance X.

When the calculation unit 24 derives the voltage V2 of the lithium ion capacitor 10 based on the increase or decrease in the capacitance X due to charging and discharging from SOC-OCV property at the time of the temperature T, the process proceeds to S205.

### S205

The calculation unit 24 calculates the resistance value R of the lithium ion capacitor (LIC) 10. The resistance value R is calculated according to Equation 1 below using the absolute value of the difference (ΔV) between the voltage V1 and the voltage V2 so as to be based only on the components of the voltage variation caused by the change in the resistance value due to the charging and discharging action.

$$R = \vert V 1 - V 2 \vert / I \qquad ( Equation 1 )$$

When the resistance value R of the lithium ion capacitor 10 is calculated by the calculation unit 24, the process proceeds to S206.

### S206

The determination unit 25 performs the degradation determination of the lithium ion capacitor 10 based on the calculated resistance value R of the lithium ion capacitor (LIC) 10. As a method of the deterioration determination, for example, it is determined that the lithium ion capacitor 10 is deteriorated if the deviation between the reference resistance value of the lithium ion capacitor 10 and the resistance value R determined in advance is equal to or larger than a predetermined threshold value. On the other hand, if the deviation is less than the predetermined threshold value, it is determined that the lithium ion capacitor 10 is not deteriorated. In this case, a plurality of thresholds may be set according to the progress of deterioration or the like.

When the determination unit 25 determines the deterioration of the lithium ion capacitor 10, LIC deterioration determination process ends.

### Operations and Effects

As described above, according to LIC deterioration determination device 20 of the lithium ion capacitor 10 according to the embodiment of the present disclosure, the resistance value R of the lithium ion capacitor 10 is calculated from the difference between the voltage V1 (the first voltage) after the charge/discharge process is performed on the lithium ion capacitor 10 and the voltage V2 (the second voltage) after the charge/discharge process is performed, which is estimated from SOC-OCV property of the lithium ion capacitor 10. Then, the deterioration state of the lithium ion capacitor 10 is determined based on the calculated resistance value R.

By this process, LIC deterioration determination device 20 can measure the resistance value R simultaneously with the charge/discharge process (capacitance measurement) of the lithium ion capacitor 10. Therefore, it is possible to shorten the time required for the deterioration determination of the lithium ion capacitor 10 and to improve the accuracy of the deterioration determination.

An embodiment of the present disclosure has been described above. The present disclosure can be regarded as not only a deterioration determination device for a lithium ion capacitor but also a deterioration determination method executed by a deterioration determination device including a processor and a memory, a control program for executing the deterioration determination method, a computer-readable non-transitory storage medium storing a control program, and a vehicle equipped with the deterioration determination device.

The deterioration determination device for a lithium ion capacitor of the present disclosure can be used in a case where the lithium ion capacitor is diagnosed to determine whether or not the lithium ion capacitor is in a deteriorated state.

What is claimed is:

1. A deterioration determination device for a lithium ion capacitor, the deterioration determination device comprising:
a storage unit configured to store a state of charge-open circuit voltage characteristic of the lithium ion capacitor;
an acquisition unit configured to acquire a voltage of the lithium ion capacitor;
a charging and discharging control unit configured to cause the lithium ion capacitor to perform a predetermined charging and discharging process;
a calculation unit configured to calculate a resistance value of the lithium ion capacitor from a difference between a first voltage after the charging and discharging process that is acquired by the acquisition unit and a second voltage after the charging and discharging process that is estimated from the state of charge-open circuit voltage characteristic; and
a determination unit configured to determine a deterioration state of the lithium ion capacitor based on the resistance value.

2. The deterioration determination device according to claim 1, wherein the determination unit is configured to determine the deterioration state of the lithium ion capacitor based on a change in the resistance value with respect to a reference resistance value of the lithium ion capacitor.

3. The deterioration determination device according to claim 1, wherein:
the storage unit is configured to store a plurality of the state of charge-open circuit voltage characteristics at different temperatures of the lithium ion capacitor;
the acquisition unit is configured to further acquire the temperature of the lithium ion capacitor; and
the calculation unit is configured to estimate the second voltage using the state of charge-open circuit voltage characteristic corresponding to the temperature acquired by the acquisition unit.

4. The deterioration determination device according to claim 1, wherein:
the storage unit is configured to store a plurality of the state of charge-open circuit voltage characteristics at different capacitances of the lithium ion capacitor; and
the calculation unit is configured to estimate the second voltage using the state of charge-open circuit voltage characteristic corresponding to the capacitance of the lithium ion capacitor.

5. The deterioration determination device according to claim 1, wherein:
the storage unit is configured to store a plurality of the state of charge-open circuit voltage characteristics at different temperatures and capacitances of the lithium ion capacitor;
the acquisition unit is configured to further acquire the temperature of the lithium ion capacitor; and
the calculation unit is configured to estimate the second voltage using the state of charge-open circuit voltage characteristic corresponding to the temperature acquired by the acquisition unit and the capacitance of the lithium ion capacitor.
